(19) United States
(12) Patent Application Publication
(10) Pub. No.: US 2011/0242714 A1
(43) Pub. Date: Oct. 6, 2011

(54) SEMICONDUCTOR INTEGRATED CIRCUIT DEVICE

(75) Inventor: Makoto Hirota, Kanagawa (JP)

(73) Assignee: OKI SEMICONDUCTOR CO., LTD., Tokyo (JP)

(21) Appl. No.: 13/072,926

(22) Filed: Mar. 28, 2011

(30) Foreign Application Priority Data
Mar. 31, 2010 (JP) 2010-081983

(51) Int. Cl. H02H 9/04; H01L 25/00

(52) U.S. Cl. 361/56; 327/565

(57) ABSTRACT

A semiconductor integrated circuit device of the invention can reduce a manufacturing cost and achieve size reduction without degrading performances. The semiconductor integrated circuit device includes an internal circuit and at least one input/output circuit. Each input/output circuit is adapted to feed an input signal from outside to the internal circuit and to output an output signal from the internal circuit to the outside. The semiconductor integrated circuit device also includes at least one first power source terminal. Each first power source terminal is associated with each input/output circuit for supplying a drive voltage to the internal circuit. The semiconductor integrated circuit device also includes at lease one second power source terminal. Each second power source terminal is associated with each input/output circuit for supplying a drive voltage to the associated input/output circuit. The semiconductor integrated circuit device also includes at least one common ground terminal. Each common ground terminal is associated with each input/output circuit for supplying a common ground voltage to the internal circuit and the associated input/output circuit. The first power source terminal, second power source terminal and common ground terminal for each input/output circuit are arranged next to each other to define a unit terminal group.

### BACKGROUND OF THE INVENTION

The present invention generally relates to a semiconductor integrated circuit device, and more particularly to a semiconductor integrated circuit device having an improved arrangement for power supply terminals and ground terminals.

### SUMMARY OF THE INVENTION

A semiconductor integrated circuit device receives electric power and ground voltage from an external power source. Thus, the semiconductor integrated circuit device has a number of terminals for receiving electric power and for receiving the ground voltage. If the semiconductor integrated circuit device is designed to send and receive signals to and from an external device, the semiconductor integrated circuit device also has a number of terminals for electrical connection to the external device. The power supply terminals and ground terminals of the semiconductor integrated circuit device are necessary for receiving drive voltage and current, and also for other purposes. For example, circuit for dealing with electrostatic discharge (ESD) and/or a bypass capacitor for dealing with noises is provided in cell areas of the power supply terminals and/or ground terminals. Thus, the power supply terminals and ground terminals are not mere “electricity receiving terminals.” The terminals have other important roles.

The semiconductor integrated circuit device often includes an internal circuit, which may include one or more logic circuits. If the number of power supply terminals and/or ground terminals is insufficient, the internal circuit in the semiconductor integrated circuit device may not be able to receive sufficient current. This in turn results in failed operation or malfunctioning of the semiconductor integrated circuit device. Further, if the number of the power supply terminals and/or ground terminals is insufficient, then some wiring from the power supply terminals (or the ground terminals) to the internal circuit becomes elongated. This in turn results in increased wire-resistances between the power supply terminals (or the ground terminals) and internal circuit. Consequently, the internal circuit encounters a large voltage drop, and the power supply voltage and/or ground voltage fluctuates. This causes malfunctioning of the semiconductor integrated circuit device. If the semiconductor integrated circuit device has to have the ESD prevention circuits in the cell areas of the power supply terminals or ground voltage terminals, but the number of the power supply terminals and/or ground voltage terminals is small, then the number of ESD prevention circuits that are connected to these terminals should correspondingly be small. This results in insufficient ESD resistance provided in the semiconductor integrated circuit device.

In view of these facts, the semiconductor integrated circuit devices are, in general, designed to have a large number of power supply terminals and ground voltage terminals as many as possible. For example, Japanese Patent Application Publication (Kokai) No. 6-252267 discloses the following arrangement. Power supply terminals for an internal circuit are provided around the internal circuit for supplying drive voltage to the internal circuit, ground terminals for the internal circuit are also provided around the internal circuit for supplying ground voltage to the internal circuit, another power supply terminals are provided around the internal circuit for supplying drive voltage to input/output circuits, and another ground voltage terminals are provided around the internal circuit for supplying ground voltage to the input/output circuits. The input/output circuits send and receive signals to and from external devices. Japanese Patent Application Kokai No. 2004-119712 teaches a similar terminal arrangement.

However, the increase of the terminals entails the increase of leads or pins. This results in the cost increase of the semiconductor integrated circuit device. Also this results in enlarged size of the semiconductor integrated circuit device. If the semiconductor integrated circuit device has a large size, it becomes difficult to use the semiconductor integrated circuit device in a small equipment or portable machine.

One object of the present invention is to provide a semiconductor integrated circuit device that can be made less expensive with small size, without degrading performances of the semiconductor integrated circuit device.

According to one aspect of the present invention, there is provided a semiconductor integrated circuit device that includes an internal circuit and at least one input/output circuit. Each input/output circuit is adapted to feed an input signal from outside to the internal circuit and to output an output signal from the internal circuit to the outside. The semiconductor integrated circuit device also includes at least one first power source terminal. Each first power source terminal is associated with each input/output circuit for supplying a drive voltage to the internal circuit. The semiconductor integrated circuit device also includes at lease one second power source terminal. Each second power source terminal is also associated with each input/output circuit for supplying a drive voltage to the associated input/output circuit. The semiconductor integrated circuit device also includes at least one common ground terminal. Each common ground terminal is also associated with each input/output circuit for supplying a common ground voltage to the internal circuit and the associated input/output circuit. The first power source terminal, second power source terminal and common ground terminal for each input/output circuit are arranged next to each other to define a unit terminal group.

In the semiconductor integrated circuit device, the ground terminal for the internal circuit also serves as the ground terminal for the input/output circuit. Therefore, it is possible to reduce wiring length between the terminals in the semiconductor integrated circuit device. This also reduces wiring length outside the semiconductor integrated circuit device. This contributes to size and cost reduction of the semiconductor integrated circuit device, without degrading performances of the semiconductor integrated circuit device.

For each unit terminal group, the first power source terminal may be connected to the internal circuit via a first power source cell. The first power source cell may include at least one of a first protective circuit and a first bypass capacitor. The second power source terminal may be connected to the associated input/output circuit via a second power source cell. The second power source cell may include at least one of a second protective circuit and a second bypass capacitor. The common ground terminal may be connected to the internal circuit and the associated input/output circuit via a common ground cell. The common ground cell may include at least one of a third protective circuit and a third bypass capacitor. The first power source cell, second power source cell and common ground cell for each input/output circuit may define a unit cell group such that the unit cell group is located next to the unit terminal group.

These and other objects, aspects and advantages of the present invention will become apparent to those skilled in the art when the following detailed description is read and understood in conjunction with the appended claims and drawings.

### BRIEF DESCRIPTION OF THE DRAWINGS

FIG. 1A illustrates a schematic plan view of a semiconductor integrated circuit device according to one embodiment of the present invention;

FIG. 1B is a cross-sectional view of the semiconductor integrated circuit device shown in FIG. 1A, taken along the line 1B-1B;

FIG. 2 shows an enlarged view of the part 2A of semiconductor integrated circuit device shown in FIG. 1A;

FIG. 3 is a block diagram of the semiconductor integrated circuit device shown in FIG. 1A;

FIG. 4 is an equivalent circuit diagram of various cells in the semiconductor integrated circuit device shown in FIG. 1A;

FIG. 5 is a schematic plan view of the semiconductor integrated circuit device mounted on a board;

FIG. 6A illustrates a plan view of another semiconductor integrated circuit device according to a second embodiment of the present invention;

FIG. 6B is an enlarged view of the part 6B of the semiconductor integrated circuit device shown in FIG. 6A;

FIG. 7A is a schematic plan view of a semiconductor integrated circuit device according to a third embodiment of the present invention;

FIG. 7B is an enlarged view of the part 7B in FIG. 7A.

### DETAILED DESCRIPTION OF THE INVENTION

Exemplary embodiments of the present invention will now be described in detail with reference to the accompanying drawings.

### Embodiment 1

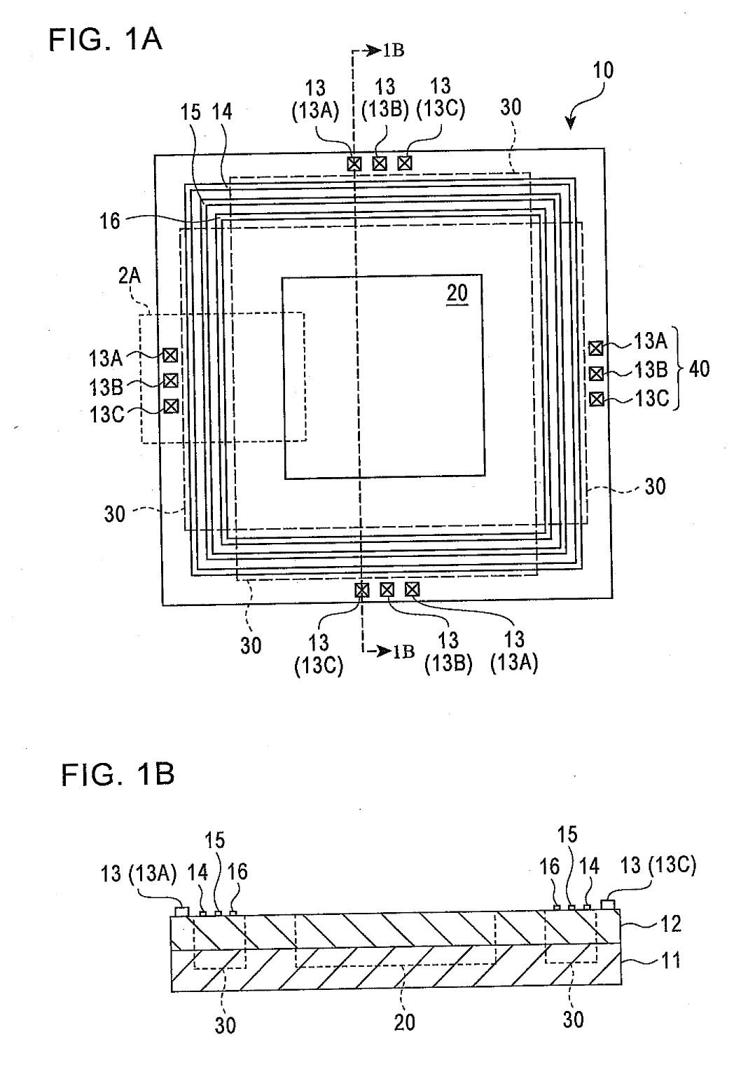

A first embodiment of the present invention will be described with reference to FIG. 1A to FIG. 5. FIG. 1A is a plan view of a semiconductor integrated circuit device 10. As shown in this drawing, the semiconductor integrated circuit device 10 has a generally square shape, when viewed from the top. In this embodiment, the size of the device 10 is 5 mm×5 mm. Referring also to FIG. 1B, the semiconductor integrated circuit device 10 includes a semiconductor substrate 11, and a multilayered wiring layer 12 on the substrate 11. The multilayered wiring layer 12 contains insulation layers and wiring layers. On an upper face of the multilayered wiring layer 12, there are provided terminals 13, power supply wiring for input/output circuits 14, power supply wiring for an internal circuit 15, and common ground potential wiring 16. It should be noted that the wiring 14 and 15 may be embedded in the multilayered wiring layer 12. The semiconductor integrated circuit device 10 includes an internal circuit (logic circuits) 20 in its center area. The semiconductor integrated circuit device 10 also includes four cell formation areas 30 around the internal circuit 20. Each of the four cell formation areas 30 extends along each side of the square semiconductor integrated circuit device 10.

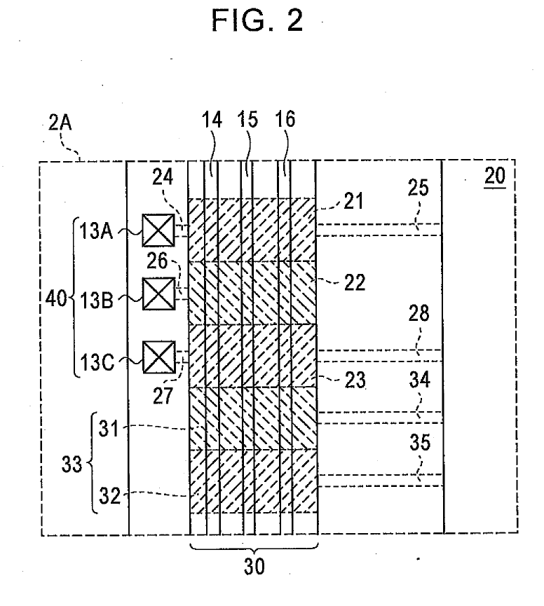

FIG. 2 shows an enlarged view of the part 2A of semiconductor integrated circuit device 10 shown in FIG. 1A. As illustrated in this drawing, each cell formation area 30 has an input cell 31 for introducing an input signal to the internal circuit 20, and an output cell 32 for sending an output signal to outside from the internal circuit 20. The input and output cells 31 and 32 define an input/output circuit 33. Each cell formation area 30 also has a power supply cell 21 to feed drive voltage to the internal circuit 20, another power supply cell 22 to feed drive voltage to the input/output circuit 33, and a ground cell 23 to feed a common ground voltage to the internal circuit 20 and input/output circuit 33.

As shown in FIG. 1B, the internal circuit 20 and cell formation areas 30 extend upward from the interior of the semiconductor substrate 11 to the upper surface of the multilayer wiring 12. The internal circuit 20 contains, for example, a CPU (central processing unit), memory circuits and peripheral circuits.

The wiring 14, 15 and 16 surround the internal circuit 20, respectively, as shown in FIG. 1A. More specifically, the common ground wiring 16 surrounds the internal circuit 20, the power supply wiring 15 for the internal circuit surrounds the common ground wiring 16, and the power supply wiring 14 for the input/output circuit surrounds the power supply wiring 15. It should be noted that the arrangement order of the three wirings 14, 15 and 16 are not limited to the illustrated one. For example, the common ground wiring 16 may not be the closest to the internal circuit 20.

The wiring 14, 15 and 16 lie on the cell formation areas 30, as best seen in FIG. 1B. Because of this arrangement, it is possible to prevent electrostatic discharge to the internal circuit 20. It is also possible to electrically connect the input/output circuit 33, the internal circuit power source cell 21 and common ground cell 23, which are all formed in each cell formation area 30, to each other. Thus, it is possible to cause the input/output circuit 33, the internal circuit power source cell 21 and common ground cell 23 to have the same potential.

The terminals 13 are arranged on the upper face of the multilayer wiring 12 along the periphery of the semiconductor integrated circuit device 10. The terminals 13 have three roles and contain three groups for the three roles, respectively. Specifically, a first group of terminals are power supply terminals 13A associated to the internal circuit for feeding a drive voltage to the internal circuit 20, a second group of terminals are power supply terminals 13B associated to the input/output circuits for feeding a drive voltage to the input/output circuits 33 formed in the cell formation areas 30, and a third group of terminals are common ground terminals 13C to feed a common ground potential to the internal circuit 20 and input/output circuits 33. One terminal 13A, one terminal 13B and one terminal 13c are arranged next to each other and define in combination a unit terminal group 40, as shown in FIG. 1A. In the illustrated embodiment, there are four unit terminal groups 40 provided on the four sides of the square circuit device 10, respectively. It should be noted, however, that the present invention is not limited in this regard. For example, two or more unit terminal groups 40 may be provided on each side of the semiconductor integrated circuit device 10. How many unit terminal groups 40 should be provided may depend on how much current should be supplied to the internal circuit 20 and/or the input/output circuits 33. Each unit terminal group 40 is associated with one input/output circuit 33. Dimensions of the terminals 13A, 13B and 13C are all the same in this embodiment.

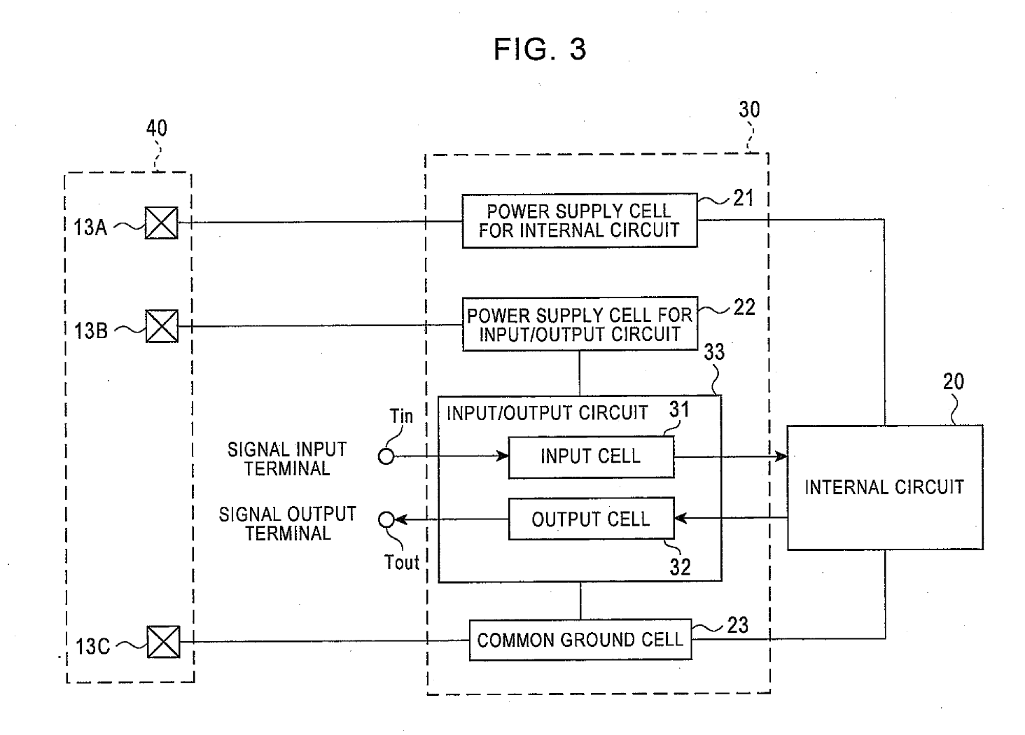

As shown in FIG. 2, a power source cell 21 for the internal circuit, a power source cell 22 for the input/output circuit and a common ground cell 23 are provided in each cell formation area 30. These cells 21, 22 and 23 are arranged next to the terminals 13A, 13B and 13C, respectively. FIG. 3 shows the block diagram of the semiconductor integrated circuit device 10, and also shows the schematic arrangement of the terminals 13A, 13B and 13C in connection with the cells 21, 22 and 23. The power source terminal 13A is connected to the power source cell 21 via internal wiring 24, and the power source cell 21 is connected to the internal circuit 20 via another internal wiring 25. The second power source cell 13B is connected to the power source cell 22 via internal wiring 26. The common ground terminal 13C is connected to a common ground cell 23 via internal wiring 27, and the common ground cell 23 is connected to the internal circuit 20 via internal wiring 28. The power source terminal 13A is also connected to the power source wiring 15 via the ground cell 21, the power source terminal 13B is also connected to the power source wiring 14 via the power source cell 22, and the ground terminal 13C is also connected to the common ground wiring 16 via the common ground cell 23. In each cell formation area 30, therefore, the three cells 21, 22 and 23 are electrically connected to each other via the wiring 14, 15 and 16.

In this embodiment, a relatively low voltage (e.g., 1.5V) is applied to the power source terminal 13A for voltage feeding to the internal circuit 20 whereas a relatively high voltage (e.g., 3.3V) is applied to the power source terminal 13B for voltage feeding to the input/output circuit power source cell 22.

The cell formation area 30 has the input cell 31 to supply the input signal, which is given from the signal input terminal Tin, to the internal circuit 20. The cell formation area 30 also has the output cell 32 to supply the output signal (e.g., calculation results obtained from the internal circuit 20) to the signal output terminal Tout. The input cell 31 and output cell 32 constitute the input/output circuit 33. The input cell 31 is connected to the internal circuit 20 via the internal wiring 34, and the output cell 32 is connected to the internal circuit 20 via another internal wiring 35. The signal input terminal Tin and signal output terminal Tout are located above the cell formation area 30 and below the wiring 14 and 15 (or wiring 15 and 16). Signals are introduced to the internal circuit 20 from the signal input terminal Tin, and the calculation results of the internal circuit 20 (i.e., output signals) are supplied from the signal output terminal Tout.

The structures shown in FIGS. 2 and 3 are also employed in other three unit terminal groups 40 in FIG. 1A. Note that there are four unit terminal groups 40 in FIG. 1A. Therefore, the cells 21, 22 and 23 associated with each unit terminal group 40 are connected to the cells 21, 22 and 23 associated with the other three unit terminal groups 40 via the wiring 14, 15 and 16.

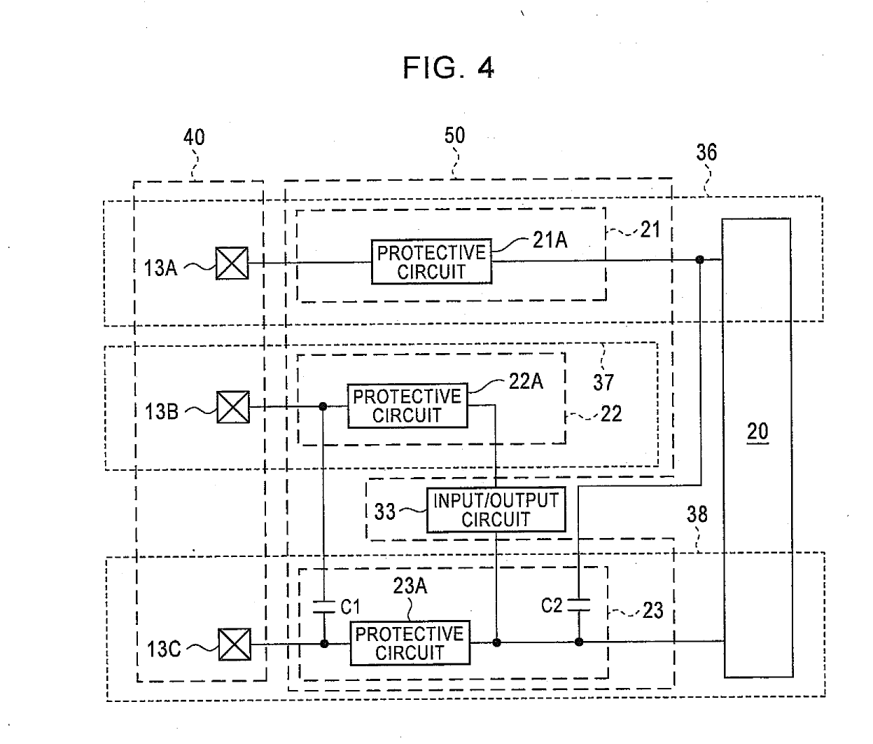

Referring now to FIG. 4, the detail of the three cells 21, 22 and 23 will be described. The power source cell 21 for the internal circuit includes a protective circuit 21A. The protective circuit 21A is, for example, used to deal with electrostatic discharge (ESD). The power source cell 22 for the input/output circuit includes a protective circuit 22A. The common ground cell 23 includes a protective circuit 23A, and bypass capacitors C1 and C2 connected to ends of the protective circuit 23A. The bypass capacitors C1 and C2 may be implemented in the form of gate capacitors of MOS transistors or ordinary capacitors on the wiring.

The common ground cell 23 is connected to the internal circuit power source cell 21 via the internal circuit 20 and to the input/output circuit power source cell 22 via the input/output circuit 33. Thus, drive currents to drive the internal circuit 20 and input/output circuit 33 flow to the common ground terminal 13C via the common ground cell 23, and further flow out of the semiconductor device 10 from the common ground terminal 13C.

As illustrated in FIG. 4, a single power source cell 21, single power source cell 22 and single ground cell 23 constitute in combination a unit cell group 50. A path from the power source terminal 13A to the internal circuit 20 is referred to as an internal circuit power supply path 36. A path from the power source terminal 13B to the power source cell 22 is referred to as an input/output signal path 37. A path from the common ground terminal 13C to the internal circuit 20 is referred to as a common ground path 38.

A process of making the semiconductor integrated circuit device 10 will now be described. First, semiconductor substrate 11 is prepared. Then, a plurality of semiconductor elements are formed in a predetermined region of the semiconductor substrate 11 by known techniques such as photolithography, ion implantation and film formation process (deposition process).

Subsequently, a multilayer wiring 12 is formed on the substrate 11 by known techniques such as photolithography and deposition process. Upon the provision of the multilayer wiring 12, the semiconductor elements are electrically connected to each other. Thus, the internal circuit 20, the power source cells 21, 22, the ground cells 23 and the input/output circuits 33 are provided. One power source cell 21, one power source cell 22 and one ground cell 23 are arranged next to each other in order to define one unit cell group 50.

The terminals 13 (13A, 13B and 13C), the wiring 14, 15 and 16, the signal input terminals Tin and the signal output terminals Tout are formed on the multilayer wiring 12 by known techniques such as photolithography and deposition process. One power source terminal 13A, one power source terminal 13B and one ground terminal 13C are arranged next to each other to define one unit terminal group 40. As shown in FIG. 4, the unit terminal group 40 is provided near and outside the corresponding unit cell group 50. Upon the provision of the unit terminal groups 40, the power source paths 31, the signal paths 32 and the common ground paths 33 are formed. The semiconductor integrated circuit device 10 is thus obtained.

Advantages of the semiconductor integrated circuit device 10 will be described. First, because the common ground terminal 13C is used as the ground terminal of the internal circuit 20 and also as the ground terminal of the input/output circuit power source cell 22, the number of ground terminals in the semiconductor integrated circuit device 10 is reduced. Thus, the semiconductor integrated circuit device 10 can be made compact.

Second, because each unit terminal group 40 includes the common ground terminal 13C and the power source terminal 13A or 13B is adjacent to the common ground terminal 13C, the path from the power source cell 21 (or 22) to the common ground cell 23 via the input/output circuit 33 (i.e., the escape route for ESD surging) is short. This improves the ESD resistance.

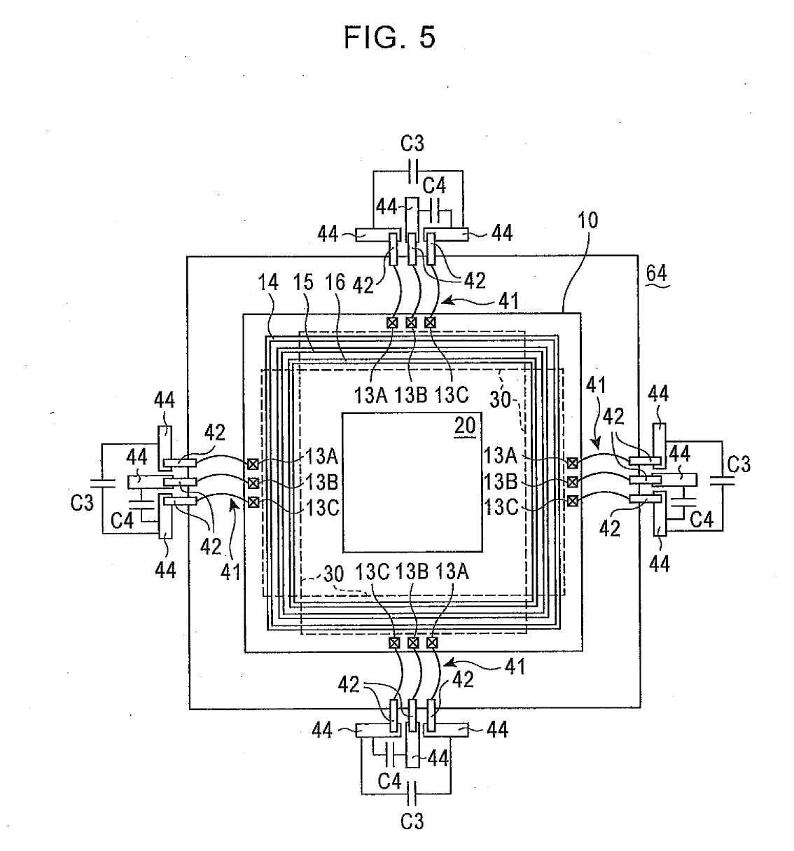

Third, the noise reduction is achieved efficiently. This will be explained with reference to FIG. 5. This drawing illustrates the semiconductor integrated circuit device 10 mounted on a mounting plate 64. The power source terminals 13A, 13B and common ground terminal 13C are connected to leads 42 by bonding wires 41. The semiconductor integrated circuit device 10, bonding wires 41 and leads 42 are sealed by resin 43, i.e., they become a packaged product. The leads 42 are coupled to corresponding pads 44 on the mounting plate 64.

The pad 44 connected to the power source terminal 13A via the bonding wire 41 and lead 42 is coupled to the pad 44 connected to the common ground terminal 13C via the bonding wire 41 and lead 42 by the bypass capacitor C3. Likewise, the pad 44 connected to the power source terminal 13B via the bonding wire 41 and lead 42 is coupled to the pad 44 connected to the common ground terminal 13C via the bonding wire 41 and lead 42 by the bypass capacitor C4. The bypass capacitors C3 and C4 are provided to reduce or eliminate noises that would appear on the path from the power source terminal 13A to the common ground terminal 13C via the power source cell 21 and internal circuit 20, and on the path from the power source terminal 13B to the common ground terminal 13C via the power source cell 22 and input/output circuit 33.

In the illustrated embodiment, the terminals 13A to 13C are positioned next to each other (or adjacent to each other) to define a unit terminal group 40. Accordingly, when the bypass capacitors C3 and C4 are connected to the terminals 13A to 13C in the same unit terminal group 40, the wiring between the terminals 13A, 13B, 13C and the bypass capacitors C3, C4 can be made short. This reduces parasitic inductance between the terminals 13A, 13B, 13C and the bypass capacitors C3, C4, and efficiently achieves noise reduction.

In this embodiment, there are provided the bypass capacitors C1 and C2 in the common ground cell 23 for noise reduction, as shown in FIG. 4. Because the terminals 13A to 13C are provided adjacent to each other, the wiring length between the terminals 13A to 13C and the bypass capacitors C1 and C2 is short, if compared to a case where the terminals are provided with some distance. Thus, the arrangement of this embodiment can achieve noise reduction in an effective manner. It should be noted, however, that the bypass capacitors C1 and C2 may not be provided in the common ground cell 23 and the protective circuit 23A may only be provided in the common ground cell 23.

The above-described advantages of the semiconductor integrated circuit device 10 are enhanced as the total number of the terminals 13 (13A to 13C) and signal input/output terminals in the circuit 10 becomes smaller. For example, the above-described advantages are obtained sufficiently when the total number of the terminals is less than one hundred, and the further enhanced advantages are obtained when the total number of the terminals is between thirty and sixty.

The positions of the three terminals 13A, 13B and 13C in each unit terminal group 40 are not limited to the illustrated ones. For example, the power source terminal 13A for the internal circuit may be positioned between the terminals 13B and 13C. In this arrangement, the power source cell 21 for the internal circuit is positioned at the center in the unit cell group 50. The arrangement of the terminals 13A, 13B and 13C in each of the unit terminal groups 40 may vary from one unit terminal group to another unit terminal group. For example, the power source terminal 13A may be at the center in one unit terminal group 40 but the power source terminal 13B may be at the center in another unit terminal group 40.

### Embodiment 2

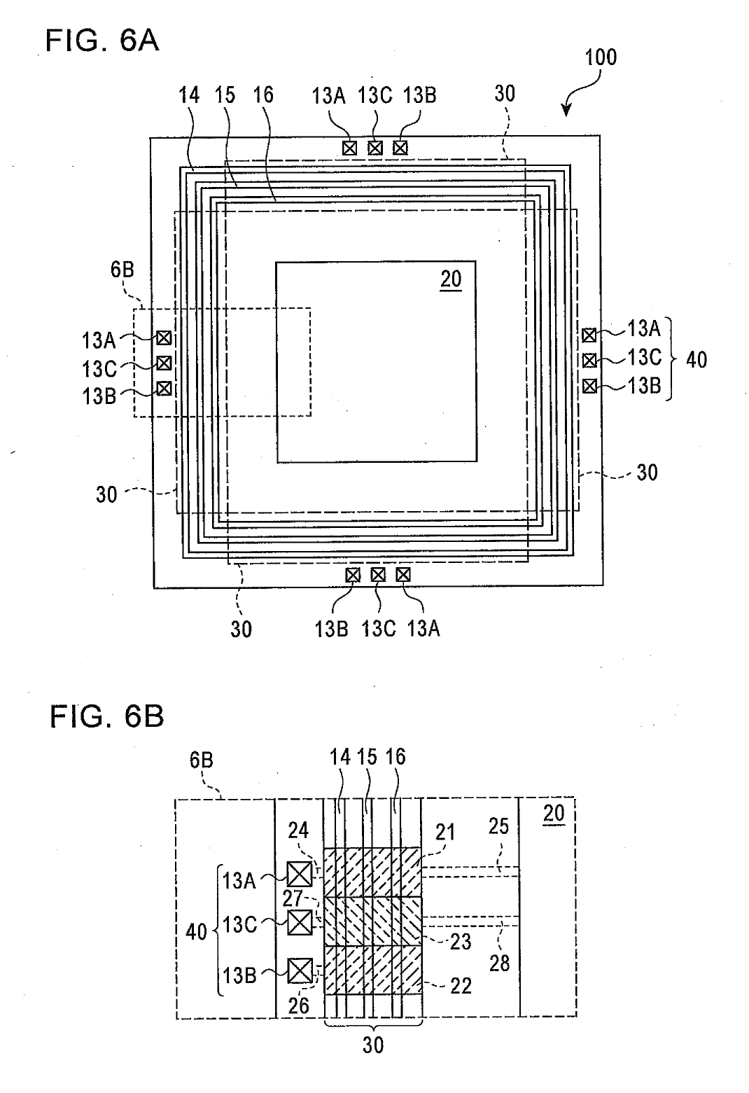

The second embodiment will be described with referent to FIGS. 6A and 6B. Similar reference numerals and symbols are used to designate same or similar elements in the first and second embodiments. In the second embodiment, the common ground cell 13C is always provided at the center in each unit terminal group 40. Accordingly the corresponding cell (i.e., the common ground cell) 23 is also provided at the center in each cell group 50. FIG. 6A is similar to FIG. 1A, and FIG. 6B is similar to FIG. 2. Reference numeral 100 designates the semiconductor integrated circuit device of the second embodiment.

This arrangement has the following advantage. The path from the power source terminal 13A to the common ground cell 13C through the internal circuit 20 and the path from the power source terminal 13B to the common ground cell 13C through the power source cell 22 can be made shorter, if compared to the arrangement of Embodiment 1. This decreases the wiring resistance and increases the ESD resistance. The paths between the terminals 13A, 13B and 13C and the bypass capacitors C3 and C4, which are located outside the semiconductor integrated circuit device (see FIG. 5), can be made shorter in the second embodiment than in the first embodiment. This contributes to further noise reduction.

### Embodiment 3

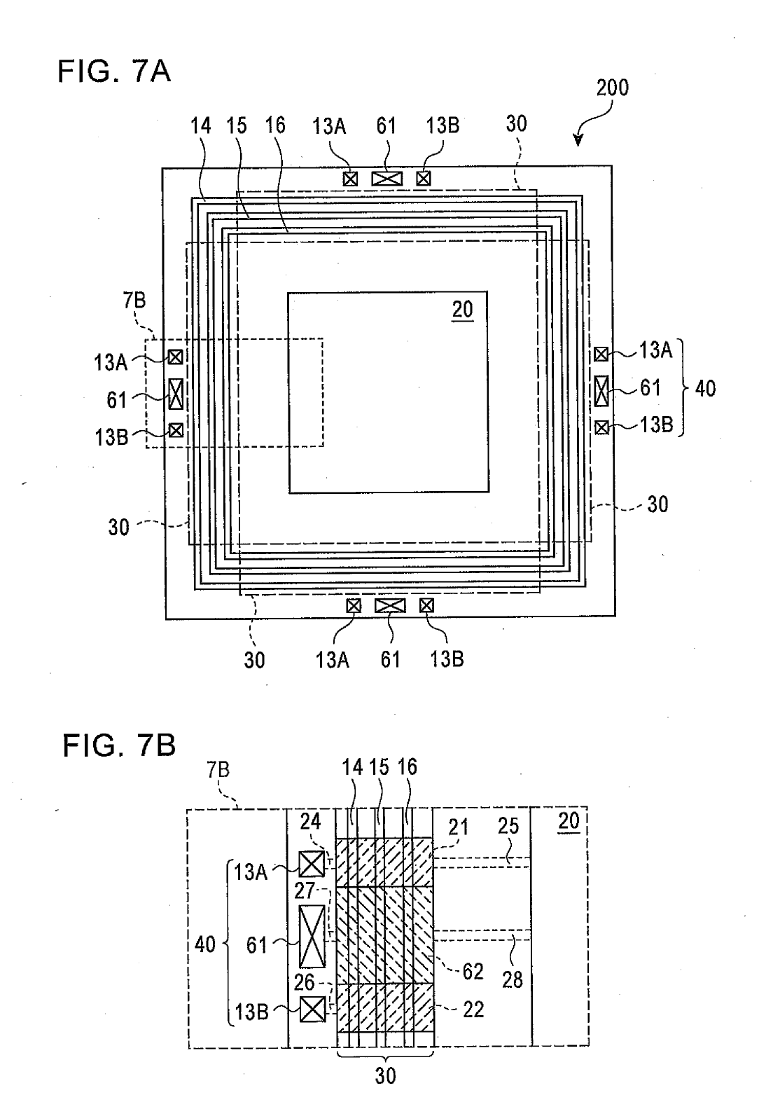

In the first and second embodiments, all the terminals 13A, 13B and 13C have the same size. It should be noted, however, that the common ground terminal 13C may have a larger size than the other terminals 13A and 13B. This arrangement will be described with reference to FIGS. 7A and 7B. FIG. 7A is similar to FIG. 1A, and FIG. 7B is similar to FIG. 2. Similar reference numerals and symbols are used to designate same or similar elements in the first and third embodiments. Reference numeral 200 designates the semiconductor integrated circuit device of the second embodiment.

The semiconductor integrated circuit device 200 of the third embodiment has a plurality of unit terminal groups 40. Each terminal group 40 includes a power source terminal 13A for the internal circuit, a power source terminal 13B for the input/output circuit, and a common ground terminal 61. The width (or size) of the common ground terminal 61 is greater than that of the terminal 13A (or 13B). The common ground cell 62 for the common ground terminal 61 also has a greater width (or size) than the other cells 21 and 22, as shown in FIG. 7B. This arrangement provides the following advantages. The common ground terminal 61 has the same function as the common ground terminal 23 of the first embodiment, which is illustrated in FIG. 3. It supplies a common ground potential to the internal circuit 20 and the input/output circuit 33 (FIG. 3). Because the sum of the electric current flowing from the two power source terminals 13A and 13B enters the common ground terminal 61, the diameter of the wire in the common ground cell 62 is made large(r) in this embodiment. The larger diameter reduces the wire resistance, and the reduced electric resistance decreases the voltage drop because a large current does not flow. This increases, in effect, an upper limit of the current in a reliable manner.

When the width of the common ground terminal 61 has an enough width to support two bonding wires, then the common ground terminal 61 can have double bonding. Specifically, two bonding wires can be connected to a single lead. Therefore, the wiring resistance between the lead and mounting pads can be reduced. This also reduces an electric resistance at the common ground terminal 61, and contributes to reduction of wiring resistance of the common ground cell 62. As a result, the upper limit of current acceptable at the common ground cell 62 increases in a reliable manner.

The present invention is not limited to the described and illustrated embodiments. For example, the unit terminal group 40 of the first embodiment and the unit terminal group 40 of the second embodiment may be used together in the single circuit arrangement 10 of the first embodiment or in the single circuit arrangement 100 of the second embodiment. Likewise, the unit terminal group 40 of the first embodiment (or the second embodiment) and the unit terminal group 40 of the third embodiment may be used together in the single circuit arrangement 10 of the first embodiment or in the single circuit arrangement 200 of the third embodiment. Also, the unit terminal groups 40 of the first, second and third embodiments may be used together in any of the first, second and third embodiments.

This application is based on Japanese Patent Application No. 2010-81983 filed on Mar. 31, 2010, and the entire disclosure thereof is incorporated herein by reference.

What is claimed is:

1. A semiconductor integrated circuit device comprising:
an internal circuit;
at least one input/output circuit, each said input/output circuit being adapted to feed an input signal from outside to the internal circuit and to output an output signal from the internal circuit to the outside;
at least one first power source terminal, each said first power source terminal being associated with each said input/output circuit for supplying a drive voltage to the internal circuit;
at lease one second power source terminal, each said second power source terminal being associated with each said input/output circuit for supplying a drive voltage to the associated input/output circuit;
at least one common ground terminal, each said common ground terminal being associated with each said input/output circuit for supplying a common ground voltage to the internal circuit and the associated input/output circuit, wherein the first power source terminal, the second power source terminal and the common ground terminal for each said input/output circuit are arranged next to each other to define a unit terminal group.

2. The semiconductor integrated circuit device of claim 1, wherein, for each said unit terminal group, the first power source terminal is connected to the internal circuit via a first power source cell, and the first power source cell includes at least one of a first protective circuit and a first bypass capacitor.

3. The semiconductor integrated circuit device of claim 2, wherein, for each said unit terminal group, the second power source terminal is connected to the associated input/output circuit via a second power source cell, and the second power source cell includes at least one of a second protective circuit and a second bypass capacitor.

4. The semiconductor integrated circuit device of claim 3, wherein, for each said unit terminal group, the common ground terminal is connected to the internal circuit and the associated input/output circuit via a common ground cell, the common ground cell includes at least one of a third protective circuit and a third bypass capacitor, and the first power source cell, the second power source cell and the common ground cell for each said input/output circuit define a unit cell group such that the unit cell group is located next to the corresponding unit terminal group.

5. The semiconductor integrated circuit device of claim 1, wherein, for each said unit terminal group, the second power source terminal is positioned between the first power source terminal and the common ground terminal in the unit terminal group.

6. The semiconductor integrated circuit device of claim 4, wherein, for each said unit terminal group, the second power source terminal is positioned between the first power source terminal and the common ground terminal in the unit terminal group.

7. The semiconductor integrated circuit device of claim 1, wherein, for each said unit terminal group, the common ground terminal is positioned between the first and second power source terminals in the unit terminal group.

8. The semiconductor integrated circuit device of claim 4, wherein, for each said unit terminal group, the common ground terminal is positioned between the first and second power source terminals in the unit terminal group.

9. The semiconductor integrated circuit device of claim 1, wherein there are provided a plurality of said input/output circuits, a plurality of said first power source terminals, a plurality of said second power source terminals, a plurality of said common ground terminals, and a plurality of said unit terminal groups in the semiconductor integrated circuit device, and a sum of the first power source terminals, the second power source terminals and the common ground terminals together with input terminals of the input/output circuit and output terminals of the input/output circuit is one hundred or less.

10. The semiconductor integrated circuit device of claim 9, wherein the sum of the first power source terminals, the second power source terminals and the common ground terminals together with the input terminals of the input/output circuit and the output terminals of the input/output circuit is between thirty and sixty.

11. The semiconductor integrated circuit device of claim 1, wherein the common ground terminal has a same width as the first power source terminal and the second power source terminal.

12. The semiconductor integrated circuit device of claim 1, wherein the common ground terminal has a wider width than the first power source terminal and the second power source terminal.

13. The semiconductor integrated circuit device of claim 1, wherein the common ground terminal has a width for connection to two bonding wires.

14. The semiconductor integrated circuit device of claim 12, wherein the common ground terminal has a width for connection to two bonding wires.

15. The semiconductor integrated circuit device of claim 4, wherein each of the first, second and third protective circuits is a circuit that deals with electrostatic discharge.
